(19) United States
(12) Patent Application Publication
(10) Pub. No.: US 2025/0206989 A1
(43) Pub. Date: Jun. 26, 2025

(54) FILM-SHAPED SINTERING MATERIAL FOR HEATING AND PRESSURIZATION, AND METHOD FOR PRODUCING SEMICONDUCTOR DEVICE

(71) Applicant: LINTEC CORPORATION, Itabashi-ku, Tokyo (JP)

(72) Inventors: Taku NEMOTO, Itabashi-ku, Tokyo (JP); Takuo NISHIDA, Itabashi-ku, Tokyo (JP); Hidekazu NAKAYAMA, Itabashi-ku, Tokyo (JP); Satoshi KIDA, Itabashi-ku, Tokyo (JP)

(73) Assignee: LINTEC CORPORATION, Itabashi-ku, Tokyo (JP)

(21) Appl. No.: 18/850,900

(22) PCT Filed: Mar. 30, 2023
(86) PCT No.: PCT/JP2023/013339

§ 371 Date: Sep. 25, 2024

(30) Foreign Application Priority Data
Mar. 31, 2022 (JP) 2022-061105

(51) Int. Cl. C09J 7/35; C09J 5/06; C09J 9/02; C09J 11/04; H01L 23/00

(52) U.S. Cl. CPC C09J 7/35; C09J 5/06; C09J 9/02; C09J 11/04; H01L 24/29; H01L 24/83; C09J 2203/326; C09J 2301/304; H01L 2224/2929; H01L 2224/29339; H01L 2224/83851

(57) ABSTRACT

A film-shaped firing material for heating and pressurizing, the material including: metal particles; and a binder component that contains a resin having a decomposition initiation temperature of 200° C. or less.

### TECHNICAL FIELD

The present disclosure relates to a film-shaped firing material for heating and pressurizing, and a method of producing a semiconductor device.

### BACKGROUND ART

In recent years, along with high voltage and high current being used in automobiles, air conditioners, personal computers, and the like, the demand for semiconductor elements (for example, power devices) to be mounted thereon has been increased. In applications such as power devices, since a semiconductor element is used under high voltage and high current, a large amount of heat is likely to be generated from the semiconductor element. Therefore, it is necessary to efficiently release the heat generated from the semiconductor element.

Conventionally, in order to release the heat, generated from a semiconductor element, to the outside, a heat-releasing member (for example, a heat sink) may be attached around the semiconductor element. In this case, a film-shaped firing material may be used to bond the heat-releasing member and the semiconductor element. Further, there is a demand to form a bonding material between a power semiconductor element and a substrate from a metal having high thermal conductivity and high heat resistance.

For example, Patent Document 1 proposes “a film-shaped firing material, comprising: sinterable metal particles; and a binder component, wherein a temperature (A), at which a negative gradient is the highest, in a thermogravimetric curve (TG curve) measured at a temperature-rising-rate of 10° C./min in a nitrogen atmosphere and a maximum peak temperature (B) in a temperature range of 25° C. to 400° C. in a differential thermal analysis curve (DTA curve) measured at a temperature-rising-rate of 10° C./min in a nitrogen atmosphere using alumina particles as a reference sample satisfy a relationship of A<B<A+60° C.”.

Patent Document 2 proposes “a joint manufacturing method comprising: a step A of preparing a laminate in which two objects to be joined are temporarily adhered via a heat-joining sheet that includes a pre-sintering layer including a thermally decomposable binder which is a solid at 23° C.; a step B of increasing a temperature of the laminate from a temperature equal to or lower than a first temperature defined below to a second temperature; and a step C of holding the temperature of the laminate in a predetermined range after the step B, wherein the laminate is pressurized during at least a part of the step B and during at least a part of the step C: the first temperature is a temperature at which an organic component contained in the pre-sintering layer is decreased by 10% by weight when the pre-sintering layer is subjected to thermogravimetric measurement; and when the step B and the step C are carried out in air, the thermogravimetric measurement is carried out in air, and when the step B and the step C are carried out in a nitrogen atmosphere, a reducing gas atmosphere or a vacuum atmosphere, the thermogravimetric measurement is carried out in a nitrogen atmosphere”.
Patent Document 1: Japanese Patent Application Laid-Open (JP-A) No. 2018-188723
Patent Document 2: Japanese Patent (JP-B2) No. 6796937

### SUMMARY OF INVENTION

### Technical Problem

It is desirable that such a firing material for bonding is sintered under mild low-temperature conditions as much as possible. In the Examples of Patent Document 2, sintering is carried out by heating and pressurizing the firing material under a condition of 200° C. or 300° C. However, in a case where sintering is carried out by pressurizing the firing material while heating the firing material, a phenomenon that voids are likely to be generated inside the sintered body has occurred. In this regard, the presence of the voids inside the sintered body may result in a decrease in thermal conductivity, a decrease in thickness uniformity, and the like.

It is an object of an embodiment of the present disclosure to provide a film-shaped firing material for heating and pressurizing, from which a sintered body with few voids can be obtained, and a method of producing a semiconductor device using the film-shaped firing material for heating and pressurizing according to the present disclosure.

### Solution to Problem

The present disclosure includes the following embodiments.

<1> A film-shaped firing material for heating and pressurizing, the material comprising:
metal particles; and
a binder component that contains a resin having a decomposition initiation temperature of 200° C. or less.

<2> The film-shaped firing material for heating and pressurizing according to <1>, wherein the resin having a decomposition initiation temperature of 200° C. or less is an aliphatic polycarbonate.

<3> The film-shaped firing material for heating and pressurizing according to <1> or <2>, wherein the resin having a decomposition initiation temperature of 200° C. or less is an aliphatic polycarbonate containing an organic acid group.

<4> The film-shaped firing material for heating and pressurizing according to any one of <1> to <3>, wherein the metal particles contain silver.

<5> The film-shaped firing material for heating and pressurizing according to any one of <1> to <4>, wherein the metal particles contain metal particles having a particle diameter of 100 nm or less.

<6> The film-shaped firing material for heating and pressurizing according to any one of <1> to <5>, wherein the film-shaped firing material for heating and pressurizing is used for bonding a semiconductor element and another component.

<7> The film-shaped firing material for heating and pressurizing according to <6>, wherein the semiconductor element is a power semiconductor element.

<8> A method of producing a semiconductor device using the film-shaped firing material for heating and pressurizing according to <6> or <7>, the method comprising:
a step of obtaining a layered body precursor by sandwiching the film-shaped firing material for heating and pressurizing between the semiconductor element and the other component; and
a step of heating and pressurizing the layered body precursor.

<9> The method of producing a semiconductor device according to <8>, wherein the step of heating and pressurizing the layered body precursor includes:
a first process of obtaining a second layered body precursor by pressurizing the layered body precursor while heating the layered body precursor at a temperature that is equal to or higher than the decomposition initiation temperature of the resin having a decomposition initiation temperature of 200° C. or less but lower than a melting point of the metal particles; and
a second process of heating the second layered body precursor at a temperature that is equal to or higher than the melting point of the metal particles.

<10> The method of producing a semiconductor device according to <8>, wherein the step of heating and pressurizing the layered body precursor includes:
a first process of obtaining a second layered body precursor by pressurizing the layered body precursor while heating the layered body precursor at a temperature that is equal to or higher than the decomposition initiation temperature of the resin having a decomposition initiation temperature of 200° C. or less but lower than 250° C.; and
a second process of heating the second layered body precursor at a temperature that is equal to or higher than 250° C.

### Advantageous Effects of Invention

According to an embodiment of the present disclosure, there is provided a film-shaped firing material for heating and pressurizing, from which a sintered body with few voids can be obtained.

According to another embodiment of the present disclosure, there is provided a method of producing a semiconductor device using the film-shaped firing material for heating and pressurizing according to the present disclosure.

### BRIEF DESCRIPTION OF DRAWINGS

FIG. 1 is a schematic cross-sectional view showing an example of a flow of obtaining a sintered body from a film-shaped firing material for heating and pressurizing according to the present disclosure.

FIG. 2 is a schematic cross-sectional view of a film-shaped firing material with a support sheet according to an embodiment of the present disclosure.

FIG. 3 is a schematic cross-sectional view of a film-shaped firing material with a support sheet according to another embodiment of the present disclosure.

FIG. 4 is a schematic perspective view of a film-shaped firing material with a support sheet according to another embodiment of the present disclosure.

FIG. 5 is a schematic cross-sectional view showing an example of a flow of obtaining a sintered body from a conventional film-shaped firing material.

### DESCRIPTION OF EMBODIMENTS

Hereinafter, an embodiment of an example of the present invention will be described. These description and example illustrate an embodiment, and do not limit the scope of the invention.

In the present specification, the upper limit value or the lower limit value of one numerical range described in stages may be replaced with the upper limit value or the lower limit value of another numerical range described in stages. In the numerical range described in the present specification, the upper limit value or the lower limit value of the numerical range may be replaced with a value shown in the Examples.

In the present disclosure, “to” representing a numerical range represents a range including numerical values respectively described as an upper limit and a lower limit thereof. In addition, in the numerical range represented by “to”, when only the upper limit value has a unit, the lower limit value has the same unit.

In the present specification, “(meth)acryl” encompasses both acryl and methacryl.

Each component may include plural kinds of corresponding substances.

In the case of reference to the amount of each component in the composition, if plural kinds of substances corresponding to each component are present in the composition, unless otherwise specified, the amount means the total amount of the plural kinds of substances present in the composition.

### <Film-Shaped Firing Material for Heating and Pressurizing>

The film-shaped firing material for heating and pressurizing according to the present disclosure contains metal particles and a binder component that contains a resin having a decomposition initiation temperature of 200° C. or less (hereinafter also referred to as a “specific resin”).

Here, the film-shaped firing material for heating and pressurizing refers to a film-shaped material for obtaining a sintered body by heating and pressurizing (for example, 100° C. or more and 0.15 MPa or more).

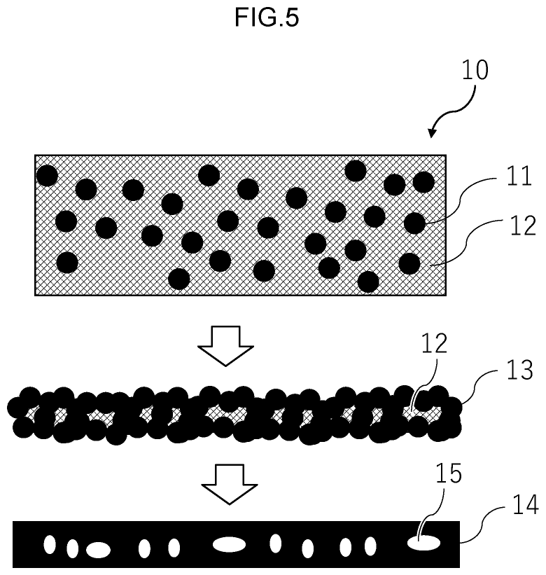

The film-shaped firing material for heating and pressurizing according to the present disclosure is, owing to the above configuration, a film-shaped firing material for heating and pressurizing, from which a sintered body with few voids can be obtained. The reason therefor is described with reference to FIG. 5. FIG. 5 shows an example of a flow of obtaining a sintered body from a conventional film-shaped firing material.

As shown in FIG. 5, conventionally, a film-shaped firing material 10 contains metal particles 11 and a binder component 12 containing a resin having a decomposition initiation temperature of more than 200° C. The conventional film-shaped firing material 10 finally becomes a sintered body 14 by heating the material so that the binder component 12 is decomposed and vaporized and the metal particles 11 are melted and bonded to each other. Here, when the melting point of the metal particles 11 is high, the temperature for sintering the film-shaped firing material 10 must be increased, and thus it is desirable that the melting point of the metal particles 11 is low. For example, since the metal particles 11 has a feature (melting point depression) that the melting point gradually decreases as the size decreases to the nano level, metal particles 11 having a low melting point can be obtained by selecting metal particles 11 having a small size. At this time, in the conventional film-shaped firing material 10, since the decomposition temperature of the resin contained in the binder component exceeds 200° C., the difference between the melting point of the metal particles 11 and the decomposition temperature of the resin may be small. In this case, the decomposition of the binder component 12 and the melting of the metal particles 11 may simultaneously proceed. As a result, a sintered body precursor 13 is likely to be formed in which the metal particles 11 have been melted and bonded to each other so as to surround the binder component 12 before a sintered body 14 is formed in which most of the binder component 12 has been decomposed. When the sintered body precursor 13 is formed, the metal particles 11 have been melted and bonded to each other, so that the shape of the particles is not maintained, and the melting point has risen. Therefore, the sintered body 14 obtained by decomposing the binder component 12 in the sintered body precursor 13 may be deficient in that voids 15 derived from the region where the binder component is present are formed. In addition, it is difficult to remelt the deficient sintered body 14 so as to exclude the voids 15 and aggregate the metal because of the melting point rise of the metal.

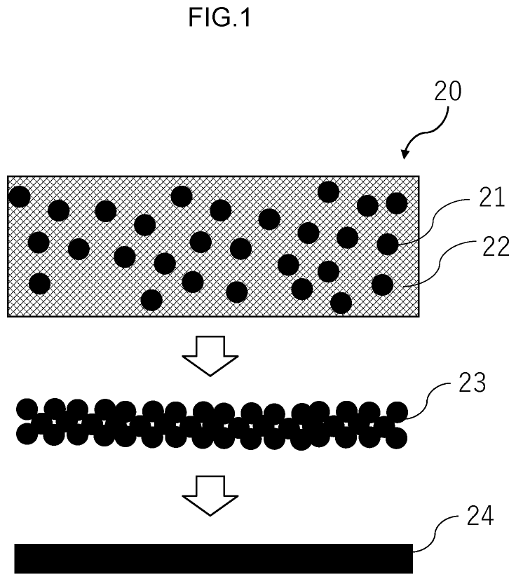

On the other hand, as shown in FIG. 1, the film-shaped firing material 20 for heating and pressurizing according to the present disclosure contains metal particles 21 and a binder component 22 containing a specific resin. The binder component 22 contains a specific resin. The decomposition initiation temperature of the specific resin is 200° C. or less. As a result, the difference between the melting point of the metal particles 21 and the decomposition temperature of the specific resin is large. Therefore, by heating and pressurizing, decomposition and vaporization of the binder component 22 proceed antecedently. In this case, the metal particles 21 are densely aggregated to obtain an aggregated body 23 of metal particles. By further heating the aggregated body 23, the metal particles are melted and bonded to each other, and a sintered body 24 can be obtained.

As described above, according to the film-shaped firing material for heating and pressurizing according to the present disclosure, the aggregated body 23 in which the metal particles are densely aggregated can be obtained, and the metal particles are unlikely to be melted and bonded to each other so as to surround the binder component. Since the metal particles 21 included in the aggregated body 23 maintain the shape of the particles, the melting point of the metal particles 21 is unlikely to rise from the initial value. Therefore, the metal particles 21 included in the aggregated body 23 are easily melted by heating to be a sintered body 24 with few voids.

Here, in the film-shaped firing material 20 for heating and pressurizing according to the present disclosure, decomposition and vaporization of the binder component 22 are promoted by heating and pressurizing to obtain the sintered body 24. In addition, by carrying out heating and pressurizing, voids included in the aggregated body 23 can be easily lost due to the pressure. In other words, when the film-shaped firing material is sintered, if pressurizing is not carried out and only heating is carried out, since voids remain in the sintered body, and for example, the metal particles 21 are bonded to each other by heating, it is difficult to obtain high thermal conductivity due to the voids preventing thermal conduction while it may be possible to increase the electrical conductivity of the sintered body.

In view of the above, the film-shaped firing material for heating and pressurizing according to the present disclosure is a film-shaped firing material for heating and pressurizing, from which a sintered body with few voids can be obtained.

The film-shaped firing material for heating and pressurizing according to the present disclosure is suitable for obtaining a sintered body by heating and pressurizing (preferably 100° C. or more and 0.15 MPa or more).

Each component contained in the film-shaped firing material for heating and pressurizing according to the present disclosure will be described below.

### (Metal Particles)

The film-shaped firing material for heating and pressurizing according to the present disclosure contains metal particles.

Owing to containing metal particles, by heating and pressurizing the film-shaped firing material for heating and pressurizing, the metal particles are melted and bonded to each other to obtain a sintered body. By forming the sintered body, the adherend in contact with the film-shaped firing material for heating and pressurizing is bonded.

Examples of the material of the metal particles include metals such as silver, gold, copper, iron, nickel, aluminum, silicon, palladium, platinum, titanium, and the like; oxides of these metals; an alloy containing at least two of these metals; barium titanate; and the like.

From the viewpoint of easily adjusting the melting point of the metal particles so that melting can be carried out at a relatively low temperature, the metal particles preferably contain silver. The silver content in the metal particles is preferably 20 mass % or more of the metal particles, and more preferably 30 mass % or more. The metal particles may be silver particles including at least one selected from the group consisting of silver and oxide of silver.

From the viewpoint of improving the dispersibility in the binder component, the surface of the metal particles may be coated with an organic substance.

Examples of the organic substance include an alcohol molecule derivative derived from an alcohol molecule having 1-12 carbon atoms, an amine molecule derivative, and the like.

The shape of the metal particles may be spherical, plate-shaped, or the like, and is preferably spherical. The spherical metal particles may be perfect spheres or ellipsoids.

The particle diameter of the metal particles may be different depending on the ratio of the contents of the sinterable metal particles and the non-sinterable metal particles to be described later, and may be 0.1 nm or more but 10000 nm or less, may be 0.3 nm or more but 3000 nm or less, or may be 0.5 nm or more but 1000 nm or less.

The particle diameter of the metal particles is measured by an electron microscope.

The method of measuring the particle diameter of the metal particles is the following procedure.

A film-shaped firing material for heating and pressurizing is observed with an electron microscope, and 100 or more metal particles are selected randomly. The project area of each of the selected metal particles is calculated, and the equivalent circle diameter corresponding to the project area is calculated. The number average value of the calculated equivalent circle diameters is defined as the particle diameter of the metal particles.

The metal particles may include two or more kinds of metal particles having different particle diameters.

Specifically, metal particles having a particle diameter of 100 nm or less and metal particles having a particle diameter of more than 100 nm may be included.

Here, the metal particles having a particle diameter of 100 nm or less are referred to as “sinterable metal particles”.

Further, the metal particles having a particle diameter of more than 100 nm are referred to as “non-sinterable metal particles”.

From the viewpoint of carrying out sintering of the film-shaped firing material for heating and pressurizing at a low temperature, the metal particles are preferably at least partially sinterable metal particles having a large melting point depression. In addition, from the viewpoint of enabling efficiently obtaining a sintered body by bonding the non-sinterable metal particles to the molten sinterable metal particles after sintering the film-shaped firing material for heating and pressurizing, it is preferable that the metal particles include both sinterable metal particles and non-sinterable metal particles.

The particle diameter of the sinterable metal particles may be selected to cause an appropriate melting point depression according to the temperature at which the film-shaped firing material for heating and pressurizing is sintered, and may be 0.1 nm or more but 100 nm or less, may be 0.3 nm or more but 50 nm or less, or may be 0.5 nm or more but 30 nm or less.

The particle diameter of the non-sinterable metal particles may be more than 150 nm but 50,000 nm or less, may be 150 nm or more but 10000 nm or less, or may be 180 nm or more but 5000 nm or less.

The particle diameter of the sinterable metal particles is measured in the same manner as the measurement procedure of the particle diameter of the above-described metal particles.

In the measurement of the particle diameter of the sinterable metal particles, the metal particles to be selected are limited to metal particles having an equivalent circle diameter corresponding to the project area of 100 nm or less.

The particle diameter of the non-sinterable metal particles is measured in the same manner as the measurement procedure of the particle diameter of the metal particles described above.

In the measurement of the particle diameter of the non-sinterable metal particles, the metal particles to be selected are limited to metal particles having an equivalent circle diameter corresponding to the project area of more than 100 nm.

From the viewpoint of improving the attachability before sintering to a semiconductor element or another component when the film-shaped firing material for heating and pressurizing is used for bonding a semiconductor element, as will be described later, while forming a sintered body with few voids, the content of the metal particles (the total content of the sinterable metal particles and the non-sinterable metal particles, the same applies hereinafter) is preferably 50 mass % or more but 98 mass % or less, more preferably 70 mass % or more but 97 mass % or less, further preferably 80 mass % or more but 95 mass % or less, and more further preferably 80 mass % or more but 90 mass % or less, with respect to the entire film-shaped firing material for heating and pressurizing.

From the viewpoint of containing a certain amount of metal particles having a large melting point depression in the film-shaped firing material for heating and pressurizing and facilitating formation of the sintered body even in low-temperature sintering, when the metal particles include sinterable metal particles, the content of the sinterable metal particles is preferably 20 mass % or more but 100 mass % or less, and more preferably 30 mass % or more but 95 mass % or less, with respect to the total content of the metal particles.

### (Binder Component)

### —Specific Resin—

The binder component contains a resin (specific resin) having a decomposition initiation temperature of 200° C. or less.

Since the decomposition initiation temperature of the specific resin is 200° C. or less, the difference between the melting point of the metal particles and the decomposition temperature of the specific resin is large. Therefore, the decomposition and vaporization of the binder component is likely to proceed antecedently by heating and pressurizing.

The decomposition initiation temperature of the resin is a value measured using a differential thermal thermogravimeter.

A differential thermal-thermogravimetric simultaneous measurement device (for example, DTG-60 manufactured by Shimadzu Corporation) is used to raise the temperature from room temperature to 400° C. at a temperature rising rate of 20° C./min under a nitrogen atmosphere to measure the decomposition behavior. The decomposition initiation temperature is the temperature at the intersection point between a line parallel to the horizontal axis passing through the mass before the start of the test heating and a tangent line drawn so that the gradient between the bending points in the decomposition curve is maximum.

From the viewpoint of easily obtaining a resin having a low decomposition initiation temperature, the specific resin is preferably an aliphatic polycarbonate.

The aliphatic polycarbonate is a polycarbonate having a main chain composed of an aliphatic hydrocarbon group and a carbonic acid group (meaning a group represented by —O—CO—O— in the present specification).

The aliphatic polycarbonate may have a side chain.

The main chain represents a relatively longest bond chain in the molecule of the compound.

The side chain represents a bond chain branched from the main chain.

The number of carbon atoms of the aliphatic hydrocarbon group contained in the main chain is preferably 1 or more but 6 or less, preferably 2 or more but 4 or less, and further preferably 2 or 3.

From the viewpoint of making it easier to obtain a resin having a low decomposition initiation temperature, the specific resin is preferably an aliphatic polycarbonate containing an organic acid group.

Examples of the organic acid group include a carboxy group and a sulfo group.

From the viewpoint of simplifying the synthesis procedure of the aliphatic polycarbonate and improving the handleability, it is preferable that the organic acid group is a carboxy group.

When the specific resin contains an organic acid group, the acidity derived from the organic acid group promotes the decomposition of the specific resin. Therefore, the decomposition initiation temperature becomes lower.

From the viewpoint of simplifying the synthesis procedure of the aliphatic polycarbonate, the aliphatic polycarbonate containing an organic acid group is preferably an aliphatic polycarbonate containing a group represented by formula (0) below.

*—(CH₂)ₘ—COOH Formula (0)

In formula (0), m represents an integer of 1 or more. * represents bonding.

From the viewpoint of reducing the influence of the side chain on the physical properties of the aliphatic polycarbonate, m is preferably 1 or more but 4 or less, more preferably 1 or more but 3 or less, and further preferably 1 or 2.

More specifically, the aliphatic polycarbonate containing an organic acid group preferably contains a constituent unit represented by formula (1) below.

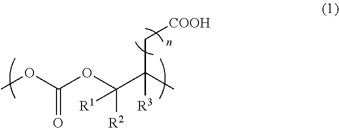

In formula (1), R¹, R² and R³ are each independently a hydrogen atom, an alkyl group having 1 to 10 carbon atoms, or an aryl group having 6 to 20 carbon atoms, and n is 1 or 2.

In formula (1), the number of carbon atoms in the alkyl group is 1 to 10, and is preferably 1 to 4.

Examples of the alkyl group include a linear or branched substituted or unsubstituted alkyl group.

Examples of the alkyl group include a methyl group, an ethyl group, a n-propyl group, an isopropyl group, a n-butyl group, a sec-butyl group, a tert-butyl group, a n-pentyl group, a n-hexyl group, a n-heptyl group, a n-octyl group, a n-nonyl group, a n-decyl group, and the like.

The alkyl group may be substituted with a substituent selected from an alkoxy group, an ester group, a silyl group, a sulfanyl group, a cyano group, a nitro group, a sulfo group, a formyl group, an aryl group, and a halogen atom.

In formula (1), the number of carbon atoms in the aryl group is 6 to 20, and is preferably 6 to 14.

Examples of the aryl group include a phenyl group, an indenyl group, a naphthyl group, a tetrahydronaphthyl group, and the like.

The aryl group may be substituted with a substituent such as an alkyl group such as a methyl group, an ethyl group, a n-propyl group, an isopropyl group, a n-butyl group, a sec-butyl group, or a tert-butyl group, another aryl group such as a phenyl group or a naphthyl group, an alkoxy group, an ester group, a silyl group, a sulfanyl group, a cyano group, a nitro group, a sulfo group, a formyl group, a halogen atom, or the like.

From the viewpoint of adjusting the number of organic acid groups present in the molecule, the aliphatic polycarbonate containing an organic acid group preferably includes a constituent unit represented by formula (2) below together with the constituent unit represented by formula (1).

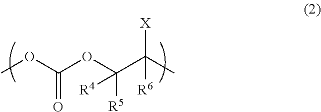

In formula (2), R⁴, R⁵ and R⁶ are each independently a hydrogen atom, an alkyl group having 1 to 10 carbon atoms, or an aryl group having 6 to 20 carbon atoms, and X is a hydrogen atom, an alkyl group having 1 to 10 carbon atoms, a haloalkyl group having 1 to 10 carbon atoms, an ether bond-containing group, an ester bond-containing group, or an allyl group.

In formula (2), the number of carbon atoms in the alkyl group is 1 to 10, and is preferably 1 to 4.

Examples of the alkyl group include a linear or branched substituted or unsubstituted alkyl group.

Examples of the alkyl group include a methyl group, an ethyl group, a n-propyl group, an isopropyl group, a n-butyl group, a sec-butyl group, a tert-butyl group, a n-pentyl group, a n-hexyl group, a n-heptyl group, a n-octyl group, a n-nonyl group, a n-decyl group, and the like.

The alkyl group may be substituted with, for example, an alkoxy group, an ester group, a silyl group, a sulfanyl group, a cyano group, a nitro group, a sulfo group, a formyl group, an aryl group, a halogen atom, or the like.

In formula (2), the number of carbon atoms in the aryl group is 6 to 20, and is preferably 6 to 14.

Examples of the aryl group include a phenyl group, an indenyl group, a naphthyl group, a tetrahydronaphthyl group, and the like.

The aryl group may be substituted with a substituent such as an alkyl group such as a methyl group, an ethyl group, a n-propyl group, an isopropyl group, a n-butyl group, a sec-butyl group, or a tert-butyl group, another aryl group such as a phenyl group or a naphthyl group, an alkoxy group, an ester group, a silyl group, a sulfanyl group, a cyano group, a nitro group, a sulfo group, a formyl group, a halogen atom, or the like.

In formula (2), X represents a hydrogen atom, an alkyl group having 1 to 10 carbon atoms, a haloalkyl group having 1 to 10 carbon atoms, an ether bond-containing group, an ester bond-containing group, or an allyl group; and X is preferably a hydrogen atom or an alkyl group having 1 to 10 carbon atoms, and more preferably a hydrogen atom or a methyl group.

The alkyl group having 1 to 10 carbon atoms represented by X is preferably an alkyl group having 1 to 4 carbon atoms. Examples of the alkyl group having 1 to 4 carbon atoms include a methyl group, an ethyl group, a n-propyl group, and the like.

The number of carbon atoms in the haloalkyl group is 1 to 10, and is preferably 1 to 4. Examples of the haloalkyl group include a fluoromethyl group, a chloromethyl group, a bromomethyl group, an iodomethyl group, and the like.

Examples of the ether bond-containing group include an alkoxy group having 1 to 4 carbon atoms, preferable examples include an alkyl group having 1 to 4 carbon atoms substituted with an allyloxy group or the like, and specific examples include a methoxymethyl group, an ethoxymethyl group, an allyloxymethyl group, and the like.

Examples of the ester bond-containing group include an acyloxy group having 1 to 4 carbon atoms, preferable examples include an alkyl group having 1 to 4 carbon atoms substituted with a benzyloxycarboxy group or the like, and specific examples include an acetoxymethyl group, a butyryloxymethyl group, and the like.

From the viewpoint of facilitating the lowering of the decomposition initiation temperature of the aliphatic polycarbonate, the content of the constituent unit represented by formula (1) in the aliphatic polycarbonate is preferably 0.001 mol % or more but 30 mol % or less, more preferably 0.1 mol % or more but 20 mol % or less, further preferably 0.5 mol % or more but 20 mol % or less, and particularly preferably 1.0 mol % or more but 20 mol % or less, in all constituent units constituting the aliphatic polycarbonate. From the viewpoint of reducing the influence of an acid on an article such as a semiconductor element to which the film-shaped firing material for heating and pressurizing according to the present disclosure is applied, the content of the constituent unit represented by formula (1) in the aliphatic polycarbonate may be 0.1 mol % or more but 5.0 mol % or less, or 0.5 mol % or more but 3.0 mol % or less, in all constituent units constituting the aliphatic polycarbonate.

The content of the constituent unit represented by formula (2) in the aliphatic polycarbonate is preferably 70 mol % or more but 99.999 mol % or less, more preferably 80 mol % or more but 99.9 mol % or less, further preferably 80 mol % or more but 99.5 mol % or less, and particularly preferably 90 mol % or more but 99.0 mol % or less, in all constituent units constituting the aliphatic polycarbonate.

From the viewpoints of easily maintaining the film shape of the film-shaped firing material for heating and pressurizing according to the present disclosure, and adjusting the viscosity of the film-forming composition, the weight-average molecular weight of the aliphatic polycarbonate is preferably 3000 or more but 1000000 or less, more preferably 10000 or more but 500000 or less, and further preferably 10000 or more but 300000 or less.

The weight average molecular weight of the aliphatic polycarbonate is a value measured by gel permeation chromatography (GPC).

The weight average molecular weight of the aliphatic polycarbonate is measured as follows.

A chloroform solution having an aliphatic polycarbonate concentration of 0.5 mass % is prepared and measured using GPC. After the measurement, the weight average molecular weight is calculated by the comparison with a polystyrene having a known weight average molecular weight measured under the same conditions. The measurement conditions are as follows.
Column: GPC column (product name of Showa Denko K. K.: Shodex K-804 L)
Column temperature: 40° C.
Eluent: chloroform
Flow rate: 1.0 mL/min

Specific examples of the aliphatic polycarbonate include an aliphatic polycarbonate in which the constituent units include only the constituent unit represented by formula (1) and the constituent unit represented by formula (2) in which R¹, R², and R³ are each a hydrogen atom and n is 1 in formula (1) and R⁴, R⁵, and R⁶ are each a hydrogen atom and X is a methyl group in formula (2).

In such an aliphatic polycarbonate, when it is synthesized such that the content of the constituent unit represented by formula (1) in the aliphatic polycarbonate is adjusted in a range of 1.0 mol % to 20 mol % in all constituent units constituting the aliphatic polycarbonate, the mass reduction rate described below can be a predetermined range, and the decomposition initiation temperature can be 200° C. or less. For example, even when the content of the constituent unit represented by formula (1) in the aliphatic polycarbonate is 3.0 mass mol % or less in all constituent units constituting the aliphatic polycarbonate, an aliphatic polycarbonate having a mass reduction rate of about 95 mass % and a decomposition initiation temperature of about 150° C. can be obtained.

From the viewpoint of facilitating the lowering of the decomposition initiation temperature of the aliphatic polycarbonate, the aliphatic polycarbonate is preferably a compound represented by formula (3) below.

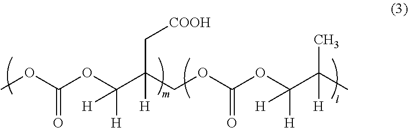

In formula (3), m and l each represent the content (unit: mol %) of the constituent unit relative to all constituent units constituting the aliphatic polycarbonate.

From the viewpoints of preventing decomposition of the binder component before heating and forming a sintered body with few voids, the decomposition initiation temperature of the aliphatic polycarbonate is preferably 80° C. or more but 185° C. or less, more preferably 100° C. or more but 170° C. or less, and further preferably 120° C. or more but 160° C. or less.

It is preferable that due to the low decomposition initiation temperature of the aliphatic polycarbonate, when heating is maintained for a certain time even at a low temperature, most of the weight of the aliphatic polycarbonate is lost by decomposition. Therefore, the mass reduction rate after one hour holding at 160° C. in thermogravimetric analysis measurement is preferably 90% or more, and more preferably 95% or more.

From the viewpoint of preventing decomposition of the binder component before heating, the mass reduction rate after one hour holding at 100° C. is preferably 5% or less, more preferably 3% or less, and further preferably 1% or less.

The decomposition initiation temperature can be adjusted by the content of the constituent unit represented by formula (1).

The mass reduction rate is measured by a thermogravimetric analysis measurement device.

As the thermogravimetric analysis measurement device, for example, DTG-60 manufactured by Shimadzu Corporation, which is a differential thermal-thermogravimetric simultaneous measurement device, can be used.

A measurement sample is added to thermogravimetric analysis measurement, the temperature is raised from room temperature to a predetermined temperature (160° C. or 100° C.) at a temperature rising rate of 50° C./min under a nitrogen atmosphere, and then the sample is held at that temperature for one hour to measure the thermal decomposition behavior. The mass reduction rate is calculated from the ratio [that is, (W0−W1)/W0×100], in which W0 is the initial mass, and W1 is the mass one hour after the heating, read from the decomposition curve.

The measurement of the decomposition initiation temperature of the aliphatic polycarbonate is as described above.

From the viewpoints of the strength of the film-shaped firing material for heating and pressurizing and the flexibility of the film-shaped firing material for heating and pressurizing, the glass transition temperature of the aliphatic polycarbonate is preferably 0° C. or more but 50° C. or less, more preferably 10° C. or more but 40° C. or less, and further preferably 15° C. or more but 30° C. or less.

The glass transition temperature of the aliphatic polycarbonate is the temperature at the peak of the differential thermal curve of the aliphatic polycarbonate, measured by the differential scanning calorimeter.

From the viewpoint of forming a sintered body with few voids, the content of the specific resin with respect to the entire binder component is preferably 50 mass % or more but 100 mass % or less, more preferably 70 mass % or more but 100 mass % or less, and further preferably 80 mass % or more but 100 mass % or less.

### —Other Resins—

The binder component may contain other resins other than the specific resin.

Examples of other resins other than the specific resin include an acrylic resin, a polylactic acid, a cellulose derivative, and the like.

The content of other resins other than the specific resin is, for example, preferably 0 mass % or more but 50 mass % or less, more preferably 0 mass % or more but 30 mass % or less, further preferably 0 mass % or more but 20 mass % or less, and particularly preferably 0 mass %, with respect to the entire binder component.

### —Content of Binder Component—

From the viewpoint of forming a sintered body with few voids, the content of the binder component is preferably 2 mass % or more but 50 mass % or less, more preferably 3 mass % or more but 30 mass % or less, further preferably 5 mass % or more but 20 mass % or less, and more further preferably 10 mass % or more but 20 mass % or less, with respect to the entire film-shaped firing material for heating and pressurizing.

### (Other Components)

The film-shaped firing material for heating and pressurizing according to the present disclosure may contain other components other than the metal particles and the binder component.

Examples of other components include a solvent, a dispersant, a plasticizer, a tackifier, a storage stabilizer, a defoaming agent, a thermal decomposition accelerator, and an antioxidant.

### (Thickness of Film-Shaped Firing Material for Heating and Pressurizing)

The thickness of the film-shaped firing material for heating and pressurizing according to the present disclosure is not particularly limited, and is preferably 10 μm or more but 200 μm or less, more preferably 20 μm or more but 150 μm or less, and further preferably 30 μm or more but 90 μm or less.

The thickness of the film-shaped firing material for heating and pressurizing is measured according to JIS K 7130 (1999).

According to JIS K 7130 (1999), the thickness is measured at any five locations of the measurement target, and the arithmetic average value of the obtained values is defined as the thickness of the film-shaped firing material for heating and pressurizing.

A constant pressure thickness measuring instrument can be used as a thickness measuring instrument.

### (Method of Producing Film-Shaped Firing Material for Heating and Pressurizing)

The method of producing the film-shaped firing material for heating and pressurizing is not particularly limited, and the material can be obtained by molding, into a film shape, a mixture (hereinafter, also referred to as a “raw material mixture”) obtained by appropriately mixing metal particles, a binder component, and optionally other components. The molding may be carried out by, for example, applying a raw material mixture onto a substrate to form a film and separating the film from the substrate.

From the viewpoint of improving film-forming properties, the raw material mixture preferably contains a solvent.

For example, the solvent preferably has a boiling point of less than 200° C. Examples of the solvent include n-hexane (boiling point: 68° C.), ethyl acetate (boiling point: 77° C.), 2-butanone (boiling point: 80° C.), n-heptane (boiling point: 98° C.), methylcyclohexane (boiling point: 101° C.), toluene (boiling point: 111° C.), acetylacetone (boiling point: 138° C.), n-xylene (boiling point: 139° C.), and dimethylformamide (boiling point: 153° C.). These may be used alone and may be used in combination.

Examples of the method of applying the raw material mixture include methods using various coaters such as an air knife coater, a blade coater, a bar coater, a gravure coater, a comma coater, a roll coater, a roll knife coater, a curtain coater, a die coater, a knife coater, a screen coater, a mayer bar coater, a kiss coater, or the like.

When the raw material mixture contains a solvent, it is preferable to heat-dry the film-shaped raw material mixture after applying the raw material mixture in a film shape.

It is preferable that the temperature at the time of heat-drying is equal to or lower than the decomposition initiation temperature of the specific resin contained in the binder component but equal to or higher than the boiling point of the solvent contained in the film-shaped raw material mixture.

The heat-drying time is not particularly limited, and the heating and drying are preferably carried out under a condition of, for example, 10 seconds or more but 10 minutes or less.

### (Application)

The film-shaped firing material for heating and pressurizing according to the present disclosure is used for, for example, the purpose of obtaining a layered body by bonding two adherends to each other.

Examples of the adherend to be bonded include, for example, a semiconductor wafer, a semiconductor element, a substrate, a lead frame, and a heat-releasing body (heat sink, etc.).

It is preferable that the film-shaped firing material for heating and pressurizing according to the present disclosure is applied to the application of bonding a semiconductor element and another component. Examples of another component to be bonded to the semiconductor element by the film-shaped firing material for heating and pressurizing according to the present disclosure include a substrate. Another component may also be a semiconductor element, and the film-shaped firing material for heating and pressurizing may be used to bond two semiconductor elements to each other.

In particular, it is preferable that the semiconductor element to be bonded is a power semiconductor element. The power semiconductor element is a semiconductor element having a rated current of 1 A or more.

The film-shaped firing material for heating and pressurizing according to the present disclosure can provide a sintered body with few voids. Therefore, the sintered body obtained by sintering the film-shaped firing material for heating and pressurizing according to the present disclosure has a high thermal conductivity. Therefore, it is possible to more efficiently release the heat generated from the semiconductor element.

Techniques, referred to as die top systems, are also known as techniques relating to power semiconductors. In such techniques, a copper foil having a special shape is attached on a die (chip) via a sintering paste. Specifically, the copper foil generally has a rectangular shape, and a copper foil having a notch at one side may be used. In this case, the first adherend is a semiconductor element, and the second adherend is a copper foil.

### (Method of Producing Layered Body)

Hereinafter, an example of a method of producing a layered body using a film-shaped firing material for heating and pressurizing according to the present disclosure will be described.

A layered body can be produced by bonding two adherends using a film-shaped firing material for heating and pressurizing according to the present disclosure. When two adherends can be bonded via the film-shaped firing material for heating and pressurizing according to the present disclosure, a layered body may be produced by any method. For example, it is also preferable to produce a layered body by the method of producing the layered body as shown below.

It is Preferable that a Method of Producing a Layered Body Includes:
a step (1) of obtaining a layered body precursor by sandwiching a film-shaped firing material for heating and pressurizing between a first adherend and a second adherend; and
a step (2) of heating and pressurizing the layered body precursor.

### (Step (1))

Step (1) is a step of obtaining a layered body precursor by sandwiching a film-shaped firing material for heating and pressurizing between a first adherend and a second adherend.

The method of sandwiching the film-shaped firing material for heating and pressurizing between the first adherend and the second adherend is, for example, as follows.

One surface of the film-shaped firing material for heating and pressurizing may be attached to a surface of the first adherend. Thereafter, the second adherend may be attached to the other surface of the film-shaped firing material for heating and pressurizing so as to face the first adherend via the film-shaped firing material for heating and pressurizing.

### (Step (2))

Step (2) is a step of heating and pressurizing the layered body precursor.

The heating temperature is preferably 150° C. or more but 600° C. or less, more preferably 165° C. or more but 500° C. or less, and further preferably 180° C. or more but 400° C. or less.

The pressure is preferably 0.15 MPa or more but 50 MPa or less.

When this step is carried out at one time at a temperature equal to or higher than the melting point of the metal particles without carrying out the first process or the second process described later, the heating and pressurizing time is, for example, preferably 5 seconds to 180 minutes, more preferably 5 seconds to 150 minutes, and further preferably 10 seconds to 120 minutes.

Step (2) may include a state in which heating and pressurizing are carried out, pressurizing may be carried out simultaneously with heating, and heating and pressurizing may be sequentially carried out, but pressurizing is preferably carried out simultaneously with heating.

The device applicable in step (2) is not particularly limited as long as it can heat and pressurize the layered body precursor.

Examples of the device include a flat press machine, a flip chip bonder, a die bonder, an autoclave, and the like, and it is preferable to use a flat press machine or an autoclave capable of giving strong pressure.

Mechanical pressurizing means (flat press machine) may be large-scaled. From the viewpoint of decreasing the frequency of use of the mechanical pressurizing means, it is preferable to use an autoclave as the device in step (2).

A procedure for using an autoclave in step (2) is, for example, as follows.

First, the layered body precursor is disposed in the autoclave. At this time, the method of disposing the layered body precursor is not particularly limited, and may be, for example, a method of placing a horizontal table in an autoclave and placing a layered body precursor thereon.

Then, the autoclave is sealed, and heating and pressurizing are carried out.

The heating method is not particularly limited, and heating may be carried out by using a heating device provided in the autoclave, or may be carried out by using an autoclave having a jacket (water vapor flow path) and flowing water vapor through the jacket.

The pressurizing method is not particularly limited, and may be, for example, a method of pressurizing by supplying a gas into an autoclave.

Examples of the gas include, but are not limited to, nitrogen, air, and the like.

In step (2), the heating and pressurizing condition may be changed in two stages.

For example, step (2) preferably includes:
a first process of obtaining a second layered body precursor by pressurizing the layered body precursor while heating the layered body precursor at a temperature that is equal to or higher than the decomposition initiation temperature of the specific resin but less than the melting point of the metal particles; and
a second process of heating the second layered body precursor at a temperature that is equal to or higher than the melting point of the metal particles.

### —First Process—

In the first process, the second layered body precursor is obtained by pressurizing the layered body precursor while heating the layered body precursor at a temperature that is equal to or higher than the decomposition initiation temperature of the specific resin but less than the melting point of the metal particles. Here, in step (2), the melting point of the metal particles means the maximum peak temperature in a temperature range of 25° C. to 400° C. in a differential thermal analysis curve (DTA curve) measured at a temperature rising rate of 10° C./min under a nitrogen atmosphere with respect to the film-shaped firing material using alumina particles as a reference sample. Specifically, the differential thermal analysis is carried out by using a thermal analysis measurement device (for example, a thermal analyzer TG/DTA simultaneous measurement device DTG-60 manufactured by Shimadzu Corporation) for the film-shaped firing material, and carrying out measurement at a temperature rising rate of 10° C./min under a nitrogen atmosphere using, as a reference sample, substantially the same amount of alumina particles as the measurement sample.

In the first process, heating and pressurizing are carried out at a temperature lower than the melting point of the metal particles. Therefore, it is possible to progress the decomposition and vaporization of the binder component while suppressing the melting of the metal particles contained in the film-shaped firing material for heating and pressurizing.

In the first process, the heating temperature is preferably equal to or higher than a temperature 15° C. higher than the decomposition initiation temperature of the specific resin, and more preferably equal to or higher than a temperature 30° C. higher than the decomposition initiation temperature of the specific resin. For example, the heating temperature may be 150° C. or higher, preferably 165° C. or higher, and more preferably 180° C. or higher.

If the heating temperature is within such a range, for example, when the decomposition initiation temperature of the specific resin is 150° C., the heating temperature can be higher than the decomposition temperature of the specific resin.

The upper limit of the heating temperature is preferably equal to or lower than a temperature 20° C. lower than the melting point of the metal particles, and more preferably equal to or lower than a temperature 40° C. lower than the melting point of the metal particles. For example, in the first process, the heating temperature may be less than 250° C., preferably 230° C. or less, and more preferably 210° C. or less.

If the heating temperature is within such a range, for example, when the melting point of the metal particles is 250° C., the heating temperature can be lower than the melting point of the metal particles. Since the decomposition initiation temperature of the specific resin is 200° C. or less, the heating temperature of the first process is easily set to a value separated from the melting point of the metal particles as well as from the decomposition initiation temperature of the specific resin as described above.

In an example, when the decomposition initiation temperature of the specific resin is 150° C. and the melting point of the metal particles is 250° C., the first process can be carried out at a heating temperature of 200° C.

Although the pressure applied to the layered body precursor may be in the range of 0.15 MPa or more but 50 MPa or less as described above, when pressurizing is carried out by an autoclave, the pressure is preferably 0.50 MPa or more but 3.00 MPa or less, more preferably 1.00 MPa or more but 3.00 MPa or less, and further preferably 1.50 MPa or more but 3.00 MPa or less. In the first process, since the layered body precursor is pressurized while being heated, the voids generated by the decomposition of the binder component can be lost, and an aggregated body in which the metal particles are densely aggregated in the second layered body precursor can be obtained. Therefore, a sintered body with few voids can be obtained by the subsequent second process.

The time of the first process is preferably changed, as appropriate, depending on the composition of the binder component and the metal particles, and for example, is preferably 5 seconds to 180 minutes, more preferably 5 seconds to 150 minutes, and further preferably 10 seconds to 120 minutes.

### —Second Process—

In the second process, the second layered body precursor is heated at a temperature that is equal to or higher than the melting point of the metal particles. From the viewpoint of obtaining a sintered body with few voids, it is also preferable to pressurize the second layered body precursor in the second process.

When carrying out the second process, a sintered body can be obtained by melting and bonding the metal particles to each other.

Since the binder component has been decomposed and vaporized through the first process, after the first process, the metal particles are densely aggregated. Therefore, the metal particles are in a state in which the metal particles are easily melted and bonded to each other without carrying out a physical pressurization process. As a result, in the second process, the sintered body can be obtained by heating the second layered body precursor under the condition of the pressure of the atmosphere as described above.

In the second process, the heating temperature is preferably 600° C. or less, more preferably 500° C. or less, and further preferably 400° C. or less. The lower limit of the heating temperature is preferably equal to or higher than a temperature 20° C. higher than the melting point of the metal particles, and more preferably equal to or higher than a temperature 40° C. higher than the melting point of the metal particles. For example, in the second process, the heating temperature may be 250° C. or higher, preferably 270° C. or higher, and more preferably 290° C. or higher. If the heating temperature is in such a range, for example, when the melting point of the metal particles is 250° C., the heating temperature is higher than the melting point of the metal particles, the melting of the metal particles reliably and quickly occurs, and the sintered body without voids can be obtained efficiently.

In an example, when the decomposition initiation temperature of the specific resin is 150° C. and the melting point of the metal particles is 250° C., the second process can be carried out at 350° C.

Although the pressure in pressurizing the second layered body precursor may be within the range of 0.15 MPa or more but 50 MPa or less as described above, when pressurizing is carried out by an autoclave, the pressure is more preferably 0.15 MPa or more but 3.0 MPa or less, and further preferably 0.5 MPa or more but 2.0 MPa or less.

The time of the second process is preferably changed, as appropriate, depending on the composition of the metal particles and the particle diameter, and for example, is preferably 1 minute or more but 30 minutes or less, more preferably 1 minute or more but 15 minutes or less, and further preferably 1 minute or more but 10 minutes or less.

It is preferable that the layered body is produced through the above steps.

<Film-Shaped Firing Material with Support Sheet>

As an example of an embodiment of a film-shaped firing material for heating and pressurizing according to the present disclosure, a film-shaped firing material with a support sheet is used which has a support sheet and a film-shaped firing material for heating and pressurizing provided on the support sheet.

In the film-shaped firing material with a support sheet according to the present disclosure, the support sheet preferably has a base film and a pressure-sensitive adhesive layer provided on the base film.

According to the film-shaped firing material with a support sheet according to the present disclosure, after obtaining a layered body of the first adherend and the film-shaped firing material with a support sheet by attaching the first adherend to the surface of the film-shaped firing material for heating and pressurizing of the film-shaped firing material with a support sheet, the support sheet is peeled from the layered body, and the exposed surface of the film-shaped firing material for heating and pressurizing (that is, the surface, which faced the support sheet side, of the film-shaped firing material for heating and pressurizing) is attached to the second adherend. As a result, a layered body can be obtained in which the first adherend, the film-shaped firing material for heating and pressurizing, and the second adherend are layered in this order.

The film-shaped firing material with a support sheet according to the present disclosure is preferably used as a dicing sheet used when obtaining a semiconductor element by cutting a semiconductor wafer into a large number of chips (hereinafter also referred to as “dicing”).

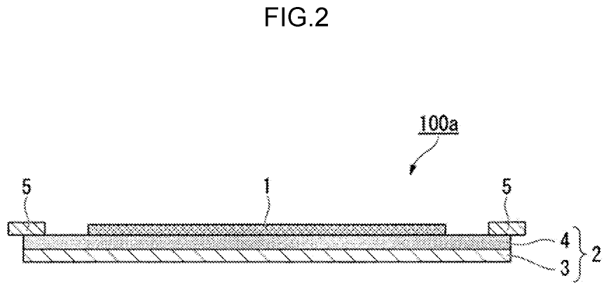

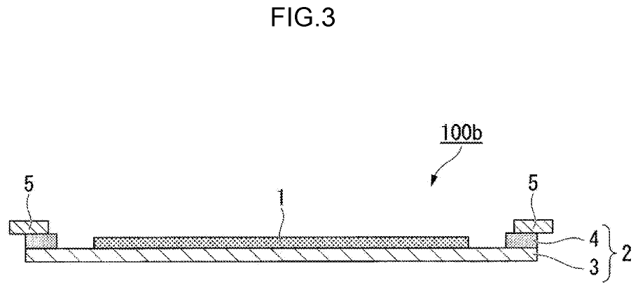

A film-shaped firing material with a support sheet will be described with reference to FIGS. 2 and 3.

The film-shaped firing material with a support sheet according to the present disclosure is not limited thereto.

FIGS. 2 and 3 each show a schematic cross-sectional view of a film-shaped firing material with a support sheet.

The film-shaped firing material with a support sheet (100a, 100b) includes a film-shaped firing material 1 for heating and pressurizing, and a support sheet 2.

As shown in FIGS. 2 and 3, the support sheet 2 preferably has a base film 3 and a pressure-sensitive adhesive layer 4.

The pressure-sensitive adhesive layer 4 facilitates the layering of the film-shaped firing material for heating and pressurizing on the support sheet, facilitates dicing described later, and can also have a function of fixing a ring frame 5. The ring frame 5 is disposed on the film-shaped firing material with a support sheet (100a, 100b) in order to fix the film-shaped firing material with a support sheet (100a, 100b) at the time of dicing a semiconductor wafer, and is not a member included in the film-shaped firing material with a support sheet (100a, 100b).

The pressure-sensitive adhesive layer 4 may be provided on the entire surface of the base film 3 as shown in FIG. 2, or may be provided along the outer periphery of the base film 3 as shown in FIG. 3.

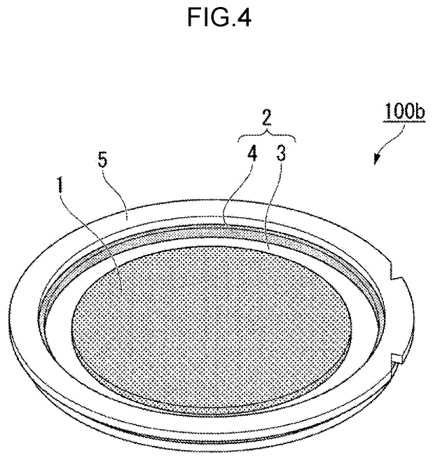

FIG. 4 shows a schematic perspective view of the film-shaped firing material with a support sheet (100b).

As shown in FIG. 4, the film-shaped firing material with a support sheet (100b) may be circular along the shape of the semiconductor wafer.

The schematic perspective view of the film-shaped firing material with a support sheet (100a) is not shown, but it may be circular along the shape of the semiconductor wafer.

Hereinafter, each configuration of the film-shaped firing material with a support sheet will be described in detail.

In this regard, reference numerals will be omitted.

### (Support Sheet)

The support sheet is not particularly limited as long as it is possible to provide a film-shaped firing material for heating and pressurizing on the support sheet.

The support sheet may have only a base film, or may have a base film and a pressure-sensitive adhesive layer provided on the base film.

From the viewpoints of adjusting attachability between the support sheet and the film-shaped firing material for heating and pressurizing, and facilitating dicing, it is preferable that the support sheet has a base film and a pressure-sensitive adhesive layer provided on the base film.

### —Base Film—

The material of the base film is not particularly limited, and examples thereof include a low-density polyethylene (LDPE), a linear low-density polyethylene (LLDPE), an ethylene-propylene copolymer, a polypropylene, a polybutene, a polybutadiene, a polymethylpentene, an ethylene-vinyl acetate copolymer, an ethylene-(meth)acrylic acid copolymer, an ethylene-methyl(meth)acrylate copolymer, an ethylene-ethyl(meth)acrylate copolymer, a polyvinyl chloride, a vinyl chloride-vinyl acetate copolymer, a polyurethane film, and an ionomer.

When higher heat resistance is required for the support sheet, examples of the material of the base film include polyesters such as polyethylene terephthalate, polybutylene terephthalate, and polyethylene naphthalate; polyolefins such as polypropylene and polymethylpentene; and the like.

When the support sheet does not have a pressure-sensitive adhesive layer, the base film surface may be treated with a release agent.

Examples of the release agent include an alkyd-based release agent, a silicone-based release agent, a fluorine-based release agent, an unsaturated polyester-based release agent, a polyolefin-based release agent, a wax-based release agent, and the like. The release agent is preferably at least one selected from the group consisting of an alkyd-based release agent, a silicone-based release agent, and a fluorine-based release agent from the viewpoint of heat resistance.

The thickness of the base film is not particularly limited, and for example, preferably 30 μm or more but 300 μm or less, and more preferably 50 μm or more but 200 μm or less.

When the thickness of the base film is within the above numerical range, the breakage of the base film is unlikely to occur even when cutting by dicing is carried out. In addition, since sufficient flexibility is imparted to the film-shaped firing material with a support sheet, good attachability to an adherend (for example, a semiconductor wafer or the like) is exhibited.

It is referable that the shape of the base film is appropriately adjusted in accordance with the shape of the adherend.

For example, when the adherend is a semiconductor wafer, the shape of the film-shaped firing material for heating and pressurizing is preferably circular.

When the shape of the base film is circular, the diameter is preferably 10 mm or more but 500 mm or less.

One type of base film may be used as the base film, or two or more kinds of base films may be layered and used.

### —Pressure-Sensitive Adhesive Layer—

The pressure-sensitive adhesive layer is a layer having pressure-sensitive adhesive property capable of fixing the film-shaped firing material on the support sheet. Further, for example, when the film-shaped firing material with a support sheet is used as a dicing sheet, the pressure-sensitive adhesive layer according to the present disclosure can fix a device (for example, a ring frame) for fixing the film-shaped firing material with a support sheet during dicing. It is preferable that the ring frame can be separated from the pressure-sensitive adhesive layer after dicing.

Examples of the material of the pressure-sensitive adhesive layer include rubber-based, acrylic, silicone-based, urethane-based, and vinyl ether-based pressure-sensitive adhesives, and the pressure-sensitive adhesive layer can be formed from a pressure-sensitive adhesive having surface unevenness, an energy ray-curable pressure-sensitive adhesive, a thermal expansion component-containing pressure-sensitive adhesive, or the like, in view of a function that can be applied to the pressure-sensitive adhesive layer.

From the viewpoint of the peelability of the film-shaped firing material for heating and pressurizing, the pressure-sensitive adhesive force against the SUS plate at 23° C. of the pressure-sensitive adhesive layer is preferably 30 mN/25 mm to 120 mN/25 mm, more preferably 50 mN/25 mm to 100 mN/25 mm, and further preferably 60 mN/25 mm to 90 mN/25 mm.

The thickness of the pressure-sensitive adhesive layer is not particularly limited, and for example, is preferably 1 μm or more but 100 μm or less, more preferably 2 μm or more but 80 μm or less, and further preferably 3 μm or more but 50 μm or less.

The pressure-sensitive adhesive layer may be disposed on the entire surface of the base film or may be disposed on a part of the base film.

When disposed on a part of the base film, the pressure-sensitive adhesive layer is preferably disposed along the contour of the shape in a plan view of the base film.

When disposed on the entire surface of the base film, the shape of the pressure-sensitive adhesive layer is the same as the shape of the base film.

When disposed on a part of the base film, the shape of the pressure-sensitive adhesive layer is preferably a ring shape.

### (Film-Shaped Firing Material for Heating and Pressurizing)

As the film-shaped firing material for heating and pressurizing included in the film-shaped firing material with a support sheet, the film-shaped firing material for heating and pressurizing according to the present disclosure is applied, and the preferred embodiments of the composition and the thickness are as described above.

Although the shape of the film-shaped firing material for heating and pressurizing is not particularly limited, it may be sheet-shaped, long film-shaped, or the like, and a long film-shaped firing material for heating and pressurizing is preferably a wound roll. From the viewpoint of reducing the amount of relatively expensive metal particles to be discarded, it is preferable to appropriately adjust the shape of the film-shaped firing material for heating and pressurizing in accordance with the shape of the adherend.

For example, when the adherend is a semiconductor wafer, the shape of the film-shaped firing material for heating and pressurizing is preferably circular.

When the shape of the film-shaped firing material for heating and pressurizing is circular, the diameter is preferably 10 mm or more but 500 mm or less.

### (Other Members)

The film-shaped firing material with a support sheet according to the present disclosure may have other members other than the support sheet and the film-shaped firing material for heating and pressurizing.

Other members include, for example, a protective sheet.

The protective sheet is a sheet for avoiding contact of the surfaces of the film-shaped firing material and the pressure-sensitive adhesive layer with the outside until the film-shaped firing material with a support sheet is used.

Examples of the protective sheet include, but are not limited to, sheets made of polyethylene, polyethylene terephthalate, polybutylene terephthalate, polyethylene naphthalate, polypropylene, and the like.

—Method of Producing Film-Shaped Firing Material with Support Sheet—

A method of producing the film-shaped firing material with a support sheet is not particularly limited, as long as a support sheet and a film-shaped firing material for heating and pressurizing can be sequentially layered.

Hereinafter, an example of the method of producing the film-shaped firing material with a support sheet is shown, but the method is not limited thereto.

### Specific Example 1 of Method of Producing Film-Shaped Firing Material with Support Sheet

A method of producing the film-shaped firing material with a support sheet (100a) in which the base film 3, the pressure-sensitive adhesive layer 4, and the film-shaped firing material 1 for heating and pressurizing are layered in this order as shown in FIG. 2, will be described.

Reference numerals will be omitted in the following.

Onto a protective sheet (other member), a mixture containing a material constituting the film-shaped firing material for heating and pressurizing and a solvent (hereinafter also referred to as a “firing material raw material mixture”) is added (for example, applied) in a film shape, and optionally the film-shaped firing material raw material mixture is heat-dried, whereby the film-shaped firing material for heating and pressurizing is formed on the protective sheet.

Meanwhile, onto a base film, a mixture containing a material constituting the pressure-sensitive adhesive layer and a solvent (hereinafter also referred to as a “pressure-sensitive adhesive layer raw material mixture”) is added (for example, applied) in a film shape, and optionally the film-shaped pressure-sensitive adhesive layer raw material mixture is heat-dried, whereby the pressure-sensitive adhesive layer is formed on the base film.

Subsequently, the exposed surface of the film-shaped firing material for heating and pressurizing formed on the protective sheet and the exposed surface of the pressure-sensitive adhesive layer formed on the base film are attached to each other to obtain the film-shaped firing material with a support sheet.

### Specific Example 2 of Method of Producing Film-Shaped Firing Material with Support Sheet

A method of producing the film-shaped firing material with a support sheet (100b) in which, on the base film 3, the pressure-sensitive adhesive layer 4 is provided along the outer periphery of the base film 3, and the film-shaped firing material 1 for heating and pressurizing is provided inside the pressure-sensitive adhesive layer 4 as shown in FIG. 3, will be described.

Reference numerals will be omitted in the following.

Onto a protective sheet (other member), a pressure-sensitive adhesive layer raw material mixture is added (for example, applied) so as to have a shape along the outer periphery of the base film. Then, to the inside of the region onto which the pressure-sensitive adhesive layer raw material mixture has been added (for example, applied) on the protective sheet (other member), a firing material raw material mixture is added (for example, applied) in a film shape. Then, by optionally heat-drying the firing material raw material mixture and the pressure-sensitive adhesive layer raw material mixture added (for example, applied) onto the protective sheet, the pressure-sensitive adhesive layer and the film-shaped firing material for heating and pressurizing are formed on the base film.

Subsequently, the exposed surfaces of the pressure-sensitive adhesive layer and the film-shaped firing material for heating and pressurizing formed on the protective sheet, and a base film, are attached to each other to obtain the film-shaped firing material with a support sheet.

(Application of Film-Shaped Firing Material with a Support Sheet)

Examples of the application of the film-shaped firing material with a support sheet include, for example, a bonding material for bonding a semiconductor element and another component (adherend) as described above, and further include a film-shaped firing material with a support sheet that also serves as a dicing sheet.

### (Method of Producing Semiconductor Device)

A method of producing a semiconductor device using a film-shaped firing material for heating and pressurizing will be described.

In the following description of the method of producing a semiconductor device, the semiconductor device refers to a layered body including an adherend, a sintered body obtained by sintering the film-shaped firing material for heating and pressurizing, and a semiconductor element, described later.

In this regard, the semiconductor element refers to a chip obtained by dicing a semiconductor wafer.

The method of producing a semiconductor device using a film-shaped firing material for heating and pressurizing preferably includes: a step of obtaining a layered body precursor by sandwiching a film-shaped firing material for heating and pressurizing between a semiconductor element and another component; and a step of heating and pressurizing the layered body precursor.

In the method of producing a semiconductor device using a film-shaped firing material for heating and pressurizing, it is preferable that the step of heating and pressurizing the layered body precursor includes: a first process of obtaining a second layered body precursor by pressurizing the layered body precursor while heating the layered body precursor at a temperature that is equal to or higher than the decomposition initiation temperature of the resin having a decomposition initiation temperature of 200° C. or less but lower than the melting point of the metal particles; and a second process of heating the second layered body precursor at a temperature that is equal to or higher than the melting point of the metal particles.

As an example of a method of using a film-shaped firing material for heating and pressurizing, a method of producing a semiconductor device using a film-shaped firing material with a support sheet that also serves as a dicing sheet, will be described.

A method of producing a semiconductor device using a film-shaped firing material with a support sheet (for example, 100a in FIG. 2 or 100b in FIG. 3) may include:
a step (1-1) of attaching a film-shaped firing material with a support sheet (for example, 100a in FIG. 2 or 100b in FIG. 3) to the back surface of a semiconductor wafer (hereinafter, simply referred to as a “semiconductor wafer”) in which a circuit is formed on a surface (front surface);
a step (1-2) of dicing the semiconductor wafer to obtain a semiconductor element;
a step (1-3) of peeling the support sheet (for example, reference numeral 2 in FIG. 2 or FIG. 3) from the semiconductor element and the film-shaped firing material for heating and pressurizing (for example, reference numeral 1 in FIG. 2 or FIG. 3) to obtain an element with a film-shaped firing material;
a step (1-4) of attaching the element with a film-shaped firing material to a surface of an adherend; and
a step (2-1) of firing the film-shaped firing material for heating and pressurizing (for example, reference numeral 1 in FIG. 2 or FIG. 3) to bond the semiconductor element and the adherend.

The steps (1-1) to (1-4) correspond to the step (1) in the method of producing a layered body described above, and the step (2-1) corresponds to the step (2) in the method of producing a layered body described above.

### —Step (1-1)—

Step (1-1) is a step of attaching the film-shaped firing material with a support sheet to the back surface of a semiconductor wafer.

The attachment is carried out so that the film-shaped firing material for heating and pressurizing in the film-shaped firing material with a support sheet is attached to the back surface of the semiconductor wafer. By doing so, a layered body A is obtained in which the support sheet, the film-shaped firing material for heating and pressurizing, and the semiconductor wafer are layered in this order.

The diameter of the semiconductor wafer is not particularly limited, and is preferably smaller than the inner diameter of the ring frame (for example, reference numeral 5 in FIG. 2 or FIG. 3).

Examples of the semiconductor wafer include: a silicon wafer; and a compound semiconductor wafer such as silicon carbide, gallium arsenide, gallium nitride, or the like. When the semiconductor element is used as a power semiconductor, if it operates at a relatively low temperature, the semiconductor wafer may be a silicon wafer, but if operation at a higher temperature is assumed, the semiconductor wafer is preferably a compound semiconductor wafer, and the compound semiconductor is preferably silicon carbide or gallium nitride.

It is preferable that a circuit is formed in advance on a surface of the semiconductor wafer. The formation of the circuit on the semiconductor wafer can be carried out by a conventionally generally used method such as an etching method or a lift-off method.

The opposite surface (back surface) of the circuit surface of the semiconductor wafer is preferably ground in advance. The grinding method is not particularly limited, and a known means using a grinder or the like may be used.

### —Step (1-2)—

Step (1-2) is a step of dicing the semiconductor wafer to obtain a semiconductor element.

More specifically, it is a step of dicing the layered body A for each circuit formed on the semiconductor wafer surface to obtain a layered body B in which the support sheet, the film-shaped firing material for heating and pressurizing, and the semiconductor element are layered in this order.

The dicing is preferably carried out so as to cut both the semiconductor wafer and the film-shaped firing material for heating and pressurizing. The dicing cut depth may be such that the film-shaped firing material for heating and pressurizing is completely cut, but is preferably such that the film-shaped firing material for heating and pressurizing is incompletely cut.

The dicing method is not particularly limited, and may be, for example, a method of singulating a wafer by a rotary round blade such as a dicing blade after fixing the peripheral portion of the support sheet (outer peripheral portion of the support) by a ring frame (for example, reference numeral 5 in FIG. 2 or FIG. 3). The means for cutting the semiconductor wafer is not limited to a cutting blade, and dicing by a laser, dicing by a plasma treatment, or the like may also be carried out. Dicing by a laser may be a dicing method in which a modified region that is a fracture starting point is formed in a semiconductor wafer by a laser, and the semiconductor wafer is fractured at the modified region by a mechanical action such as expansion of the support sheet.

### —Step (1-3)—

Step (1-3) is a step of peeling the support sheet from the semiconductor chip and the film-shaped firing material for heating and pressurizing to obtain an element with a film-shaped firing material.

The step of peeling the support sheet from the semiconductor element and the film-shaped firing material for heating and pressurizing in the layered body B is not particularly limited, and a method using a collet or the like may be used.

By peeling the support sheet from the semiconductor element and the film-shaped firing material for heating and pressurizing, a layered body C (an element with a film-shaped firing material) can be obtained in which the film-shaped firing material for heating and pressurizing and the semiconductor element are layered in this order.

### —Step (1-4)—

Step (1-4) is a step of attaching the element with a film-shaped firing material to a surface of the adherend.

Specifically, it is a step of attaching the element with a film-shaped firing material to a surface of the adherend by bringing the surface of the adherend into contact with the surface, having a film-shaped firing material for heating and pressurizing, of the chip with a film-shaped firing material.

In this step, a layered body D can be obtained in which the adherend, the film-shaped firing material for heating and pressurizing, and the semiconductor element are layered in this order.

Examples of the adherend include, but are not particularly limited to, a substrate, another semiconductor element, a lead frame, a heat-releasing body, and the like. As the heat-releasing body, for example, a heat sink, a heat pipe, or the like, made of a metal plate such as a copper plate, can be used.

### —Step (2-1)—

Step (2-1) is a step of firing the film-shaped firing material for heating and pressurizing to bond the semiconductor element and the adherend.

By firing the film-shaped firing material for heating and pressurizing, the binder component contained in the film-shaped firing material for heating and pressurizing is decomposed and vaporized, and the metal particles are melted, so that a sintered body is formed. The sintered body bonds the semiconductor element and the adherend, so that a semiconductor device can be obtained.

The conditions for firing the film-shaped firing material for heating and pressurizing may be the conditions described in step (2) in the method of producing a layered body described above, and in the present step (2-1), the first process and the second process may be carried out.

### Modification Example

In the present example, in step (1-1), a film-shaped firing material with a support sheet is attached to the back surface of the semiconductor wafer, but the method of producing a semiconductor device according to the present disclosure may be carried out such that a film-shaped firing material for heating and pressurizing is attached to an already-diced semiconductor element, and thereafter the step (1-4) and the step (2-1) are carried out. In this case, it is preferable to produce the film-shaped firing material for heating and pressurizing in substantially the same shape as that of the semiconductor element in advance.

### DESCRIPTION OF REFERENCE NUMERALS

100a, 100b: Film-shaped firing material with support sheet
1: Film-shaped firing material for heating and pressurizing
2: Support sheet
3: Base film
4: Pressure-sensitive adhesive layer
5: Ring frame
10: Film-shaped firing material
11: Metal particle
12: Binder component
13: Sintered body precursor
14: Sintered body
15: Void
20: Film-shaped firing material for heating and pressurizing
21: Metal particle
22: Binder component
23: Aggregated body
24: Sintered body

The disclosure of Japanese Patent Application No. 2022-061105, filed on Mar. 31, 2022, is incorporated in the present specification by reference in its entirety.

All documents, patent applications, and technical standards disclosed in the present specification are incorporated herein by reference to the same extent as if the individual documents, patent applications, and technical standards were specifically and individually marked as being incorporated by reference.

1. A film-shaped firing material for heating and pressurizing, the material comprising:
metal particles; and
a binder component that contains a resin having a decomposition initiation temperature of 200° C. or less.

2. The film-shaped firing material for heating and pressurizing according to claim 1, wherein the resin having a decomposition initiation temperature of 200° C. or less is an aliphatic polycarbonate.

3. The film-shaped firing material for heating and pressurizing according to claim 1, wherein the resin having a decomposition initiation temperature of 200° C. or less is an aliphatic polycarbonate containing an organic acid group.

4. The film-shaped firing material for heating and pressurizing according to claim 1, wherein the metal particles contain silver.

5. The film-shaped firing material for heating and pressurizing according to claim 1, wherein the metal particles contain metal particles having a particle diameter of 100 nm or less.

6. The film-shaped firing material for heating and pressurizing according to claim 1, wherein the film-shaped firing material for heating and pressurizing is used for bonding a semiconductor element and another component.

7. The film-shaped firing material for heating and pressurizing according to claim 6, wherein the semiconductor element is a power semiconductor element.

8. A method of producing a semiconductor device using the film-shaped firing material for heating and pressurizing according to claim 6- or 7, the method comprising:
a step of obtaining a layered body precursor by sandwiching the film-shaped firing material for heating and pressurizing between the semiconductor element and the other component; and
a step of heating and pressurizing the layered body precursor.

9. The method of producing a semiconductor device according to claim 8, wherein the step of heating and pressurizing the layered body precursor includes:
a first process of obtaining a second layered body precursor by pressurizing the layered body precursor while heating the layered body precursor at a temperature that is equal to or higher than the decomposition initiation temperature of the resin having a decomposition initiation temperature of 200° C. or less but lower than a melting point of the metal particles; and
a second process of heating the second layered body precursor at a temperature that is equal to or higher than the melting point of the metal particles.

10. The method of producing a semiconductor device according to claim 8, wherein the step of heating and pressurizing the layered body precursor includes:
a first process of obtaining a second layered body precursor by pressurizing the layered body precursor while heating the layered body precursor at a temperature that is equal to or higher than the decomposition initiation temperature of the resin having a decomposition initiation temperature of 200° C. or less but lower than 250° C.; and
a second process of heating the second layered body precursor at a temperature that is equal to or higher than 250° C.

11. The film-shaped firing material for heating and pressurizing according to claim 2, wherein the resin having a decomposition initiation temperature of 200° C. or less is an aliphatic polycarbonate containing an organic acid group.

12. The film-shaped firing material for heating and pressurizing according to claim 4, wherein the metal particles contain metal particles having a particle diameter of 100 nm or less.

13. A method of producing a semiconductor device using the film-shaped firing material for heating and pressurizing according to claim 7, the method comprising:
a step of obtaining a layered body precursor by sandwiching the film-shaped firing material for heating and pressurizing between the semiconductor element and the other component; and
a step of heating and pressurizing the layered body precursor.
